(19) United States
(12) Patent Application Publication
(10) Pub. No.: US 2024/0009789 A1
(43) Pub. Date: Jan. 11, 2024

(54) CLEANING TOOL AND WORKPIECE PROCESSING METHOD

(71) Applicant: DISCO CORPORATION, Tokyo (JP)

(72) Inventor: Kenji TAKENOUCHI, Tokyo (JP)

(21) Appl. No.: 18/345,120

(22) Filed: Jun. 30, 2023

(30) Foreign Application Priority Data
Jul. 5, 2022 (JP) 2022-108424

(51) Int. Cl. B23Q 11/00; B23Q 11/10

(52) U.S. Cl. CPC B23Q 11/0075; B23Q 11/10

(57) ABSTRACT

There is provided a cleaning tool which is used in a state of being mounted to a spindle configured such that an annular cutting blade containing abrasive grains is mountable thereto, and which is used to remove swarf that has been generated during processing of a workpiece by use of the cutting blade and that is present in a processed region processed by the cutting blade of the workpiece, from the processed region. The cleaning tool has in its central part an opening to be used at the time of mounting to the spindle. The cleaning tool is formed in an annular shape from an elastic material softer than the workpiece and does not contain abrasive grains, or the cleaning tool is formed in an annular shape from an elastic material having a Vickers hardness of less than 10.6 GPa and does not contain abrasive grains.

### BACKGROUND OF THE INVENTION

### Field of the Invention

The present invention relates to a cleaning tool to be used at the time of removing swarf generated during processing from a workpiece, and a workpiece processing method in which the cleaning tool is used.

### Description of the Related Art

In electronic apparatuses represented by mobile phones and personal computers, a device chip including a device such as an electronic circuit is an indispensable constituent element. The device chip is obtained, for example, by partitioning a front surface side of a wafer formed of such a material as silicon (Si) into a plurality of regions by rectilinear scheduled processing lines called streets, then forming a device in each of the regions, and thereafter dividing the wafer along the streets.

In the processing for dividing the wafer into the device chips, for example, an annular processing tool called a cutting blade in which abrasive grains are dispersed in a bonding material is used. With the cutting blade rotated at high speed and while liquid such as water is being supplied, the cutting tool is made to cut into the streets of the wafer, so that the wafer is cut along the streets and is divided into a plurality of device chips.

Incidentally, when a plate-shaped workpiece such as the wafer is processed by the cutting blade, swarf generated upon processing may stagnate in and adhere to the processed region processed in a groove shape (step shape), thereby lowering the quality of the device chips. In view of this, there has been proposed a technology in which, while liquid such as water is being supplied, the cutting blade is made to again pass through the groove-shaped processed region, so that the swarf stagnating in the processed region is discharged (see, for example, Japanese Patent Laid-open No. 2009-76823).

### SUMMARY OF THE INVENTION

However, in the above-mentioned technology in which the cutting blade is made to again pass through the groove-shaped processed region, for example, a slight deviation of a positional relation between the cutting blade and the processed region from a proper relation would cause the cutting blade to make contact with the processed region, resulting in generation of new swarf. In other words, in this case, the swarf would be left in the processed region.

Accordingly, it is an object of the present invention to provide a cleaning tool by which the swarf present in the processed region obtained after processing can suitably be removed, and a workpiece processing method in which the cleaning tool is used.

In accordance with an aspect of the present invention, there is provided a cleaning tool which is used in a state of being mounted to a spindle configured such that an annular cutting blade containing abrasive grains is mountable thereto, and which is used to remove swarf that has been generated during processing of a workpiece by use of the cutting blade and that is present in a processed region processed by the cutting blade of the workpiece, from the processed region. The cleaning tool has in its central part an opening to be used at the time of mounting to the spindle. The cleaning tool is formed in an annular shape from an elastic material softer than the workpiece and does not contain abrasive grains, or the cleaning tool is formed in an annular shape from an elastic material having a Vickers hardness of less than 10.6 GPa and does not contain abrasive grains.

In accordance with another aspect of the present invention, there is provided a workpiece processing method to be used when processing a plate-shaped workpiece, the workpiece processing method including a processing step of causing a cutting blade being rotated to cut into the workpiece while supplying liquid to the cutting blade, to thereby process the workpiece, and a swarf removing step of bringing a cleaning tool being rotated close to a processed region processed by the cutting blade of the workpiece while supplying liquid to the cleaning tool, to thereby remove swarf present in the processed region. The cleaning tool is formed in an annular shape from an elastic material softer than the workpiece and does not contain abrasive grains, or the cleaning tool is formed in an annular shape from an elastic material having a Vickers hardness of less than 10.6 GPa and does not contain abrasive grains.

Preferably, in the processing step, the cutting blade is caused to cut into a rectilinear scheduled processing line set on the workpiece, to thereby form the workpiece with a rectilinear processing mark, and in the swarf removing step, the cleaning tool is caused to pass through the processed region formed with the processing mark, to thereby remove the swarf present in the processed region. In addition, preferably, in the swarf removing step, the liquid supplied to the cleaning tool contains a chemical agent having a cleaning power.

Since the cleaning tool according to each aspect of the present invention is formed from a soft elastic material and does not contain abrasive grains, even if the positional relation between the cleaning tool and the processed region is deviated from a proper relation and the cleaning tool makes contact with the processed region, new generation of a large amount of swarf as in the case where the cutting blade makes contact with the processed region would not occur. Therefore, with the cleaning tool and the workpiece processing method according to each aspect of the present invention, the swarf present in the processed regions after processing is removed more suitably.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting a cutting apparatus;

FIG. 2 is a plan view depicting a workpiece;

FIG. 3 is an exploded perspective view of a first cutting unit to which a cutting blade is mounted;

FIG. 4 is an exploded perspective view of a second cutting unit to which a cleaning tool is mounted;

FIG. 5 is a plan view depicting the manner in which the workpiece is processed along a scheduled processing line;

FIG. 6 is a plan view depicting the manner in which the workpiece is processed along another scheduled processing line;

FIG. 7 is a plan view depicting the manner in which swarf present in a processed region is removed; and

FIG. 8 is a plan view depicting the workpiece obtained after processing.

### DETAILED DESCRIPTION OF THE PREFERRED EMBODIMENT

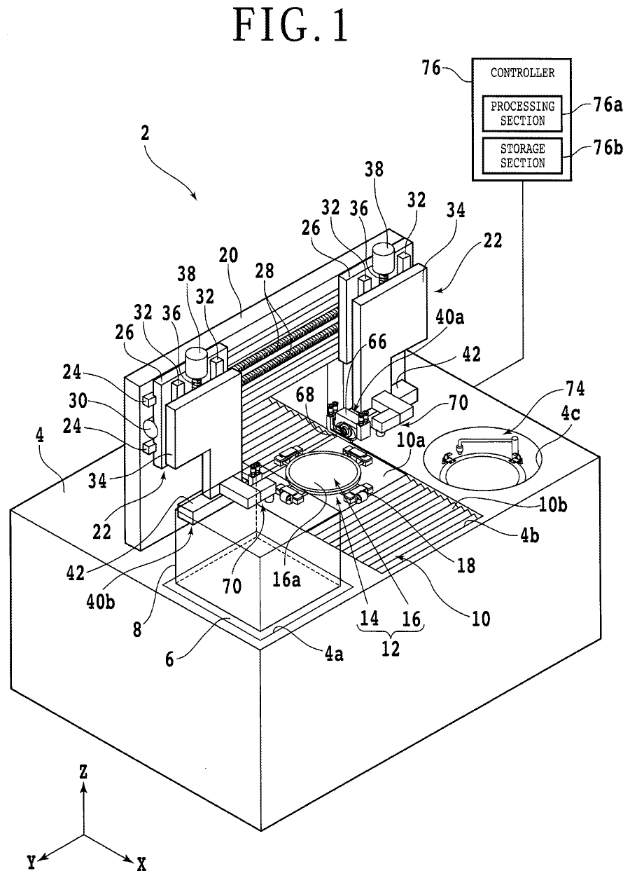

An embodiment of the present invention will be described below with reference to the attached drawings. FIG. 1 is a perspective view depicting a cutting apparatus 2 for use in the present embodiment. Note that, in FIG. 1, some of the constituent elements are expressed in functional blocks. In addition, an X axis (processing-feed axis), a Y axis (indexing-feed axis), and a Z axis (vertical axis) used in the following description are orthogonal to one another.

As depicted in FIG. 1, the cutting apparatus 2 includes a base 4 that supports various constituent elements. An opening 4a is formed in a corner of an upper surface of the base 4, and a cassette table 6 raised and lowered by an elevating mechanism (not illustrated) is disposed inside the opening 4a. A cassette 8 capable of accommodating plate-shaped workpieces is placed on an upper surface of the cassette table 6. Note that, in FIG. 1, only the outline of the cassette 8 is depicted for convenience of explanation.

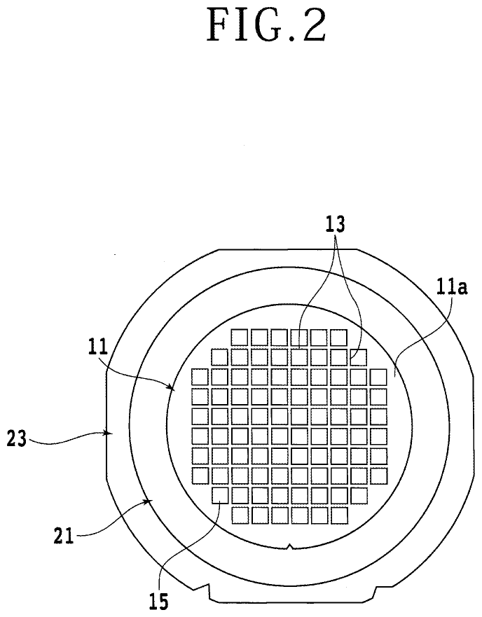

FIG. 2 is a plan view depicting a plate-shaped workpiece 11. The workpiece 11 is typically a disk-shaped wafer including a semiconductor formed of silicon (Si) or the like and has a circular front surface 11a and a circular back surface (not illustrated) on a side opposite to the front surface 11a. The front surface 11a side of the workpiece 11 is partitioned into a plurality of small regions by a plurality of intersecting rectilinear scheduled processing lines (streets) 13, and a device 15 such as an integrated circuit (IC) is formed in each of the small regions.

As depicted in FIG. 2, a tape (dicing tape) 21 larger in diameter than the workpiece 11 is affixed to the back surface side of the workpiece 11. In addition, to a peripheral part of the tape 21, an annular frame 23 is fixed in such a manner as to surround the workpiece 11. The workpiece 11 is accommodated in the cassette 8 in the state of being supported by the frame 23 through the tape 21 in this manner.

Note that the disk-shaped wafer including a semiconductor formed of silicon or the like is the workpiece 11 in the present embodiment, but the material, shape, structure, size, and the like of the workpiece 11 are not limited to any specific kind. For example, a substrate including a material such as another semiconductor, ceramic, resin, or metal may be used as the workpiece 11. Similarly, the kind, quantity, shape, structure, size, layout, and the like of the device 15 are not limited to any specific kind. The workpiece 11 may not be formed with the devices 15. In addition, the workpiece 11 may not necessarily be supported by the frame 23 through the tape 21.

As depicted in FIG. 1, at a position adjacent to the cassette table 6 along the Y axis, an opening 4b elongated in a direction along the X axis is formed. A ball-screw type chuck table moving mechanism (processing-feed mechanism) 10 is disposed inside the opening 4b. The chuck table moving mechanism 10 includes a rotational drive source (not illustrated) such as a motor connected to an end part of a ball screw, and an X-axis moving table (not illustrated) having a nut section coupled to the ball screw, and moves the X-axis moving table along the X axis.

An upper side of the X-axis moving table is covered by a table cover 10a. In addition, at both end parts in the direction along the X axis of the table cover 10a, there are attached bellows-like dustproof droplet-proof covers 10b that contract and extend according to the movement of the X-axis moving table and the table cover 10a. At an upper part of the X-axis moving table, a chuck table 12 for holding the workpiece 11 is disposed in the manner of being exposed from the table cover 10a.

The chuck table 12 is connected to a rotational drive source (not illustrated) such as a motor and is rotated around a rotational axis which is substantially parallel to the Z axis. In addition, the chuck table 12 is moved (processing-fed) along the X axis together with the X-axis moving table by the above-described chuck table moving mechanism 10.

The chuck table 12 includes, for example, a disk-shaped frame body 14 formed of metal represented by stainless steel. On an upper surface side of the frame body 14, there is formed a recess which is open at an upper end thereof in a circular shape. A disk-shaped holding plate 16 coincident in shape with the recess is fitted in the recess. In the periphery of the frame body 14, four clamps 18 for fixing the annular frame 23 supporting the workpiece 11 are disposed.

The holding plate 16 is formed, for example, in a porous plate shape from such a material as ceramic and holds the workpiece 11 by an upper surface (holding surface) 16a thereof. Note that the upper surface 16a of the holding plate 16 is substantially parallel to the X axis and the Y axis in a state in which the holding plate 16 is fitted in the recess. In other words, the chuck table 12 is rotated around a rotational axis which is substantially perpendicular to the upper surface 16a of the holding plate 16.

A bottom of the recess of the frame body 14 is connected with a suction source (not illustrated) through a flow channel (not illustrate) formed inside the frame body 14, a valve (not illustrated) disposed outside the frame body 14, and the like. Hence, when the valve is opened, a negative pressure of the suction source acts on the upper surface 16a of the holding plate 16 through the flow channel and the like. As the suction source, there is used, for example, a vacuum pump in which an air supply source and an ejector are combined with each other. It is to be noted, however, that a rotary pump or the like may be used as the suction source.

On an upper side of the opening 4b, one or a plurality of conveying mechanisms (not illustrated) capable of conveying the above-mentioned workpiece 11 (frame 23) to the chuck table 12 and the like are disposed. The workpiece 11 conveyed by the conveying mechanism or mechanisms is placed on the upper surface 16a of the chuck table 12, for example, in such a manner that the front surface 11a side thereof is exposed to the upper side.

A gate-shaped support structure 20 straddling the opening 4b along the Y axis is provided on the upper surface of the base 4. At an upper part of the support structure 20, a pair of cutting unit moving mechanisms (indexing-feed mechanisms, cutting-in-feed mechanisms) 22 are disposed. Note that the structures of the paired cutting unit moving mechanisms 22 are substantially the same except that they are configured to mutually be symmetrical (in a relation of mirror images) with respect to a plane parallel to the X axis and the Z axis. The same constituent elements of the cutting unit moving mechanisms 22 are denoted by the same reference symbols, and overlapping descriptions are omitted.

The cutting unit moving mechanisms 22 share a pair of Y-axis guide rails 24 that are fixed to a front surface of the support structure 20 and are substantially parallel to the Y axis. To the pair of Y-axis guide rails 24, Y-axis moving plates 26 constituting the respective cutting unit moving mechanisms 22 are attached in the manner of being slidable along the Y axis. On a back surface side (rear surface side) of each Y-axis moving plate 26, a nut section (not illustrated) constituting a ball screw is provided, and to each nut section, a screw shaft 28 substantially parallel to the Y-axis guide rails 24 is coupled in a rotatable manner.

To one end part of each screw shaft 28, a rotational drive source 30 such as a motor is connected. By rotating the screw shaft 28 by each rotational drive source 30, the corresponding Y-axis moving plate 26 is moved along the Y-axis guide rails 24. To a front surface of each Y-axis moving plate 26, a pair of Z-axis guide rails 32 substantially parallel to the Z axis are fixed. To the pair of Z-axis guide rails 32 fixed to each Y-axis moving plate 26, a Z-axis moving plate 34 is attached in the manner of being slidable along the Z axis.

On a back surface side (rear surface side) of each Z-axis moving plate 34, a nut section (not illustrated) constituting a ball screw is provided, and to each nut section, a screw shaft 36 substantially parallel to the Z-axis guide rails 32 is coupled in a rotatable manner. To one end part of each screw shaft 36, a rotational drive source 38 such as a motor is connected. By rotating the screw shaft 36 by each rotational drive source 38, the corresponding Z-axis moving plate 34 is moved along the Z-axis guide rails 32.

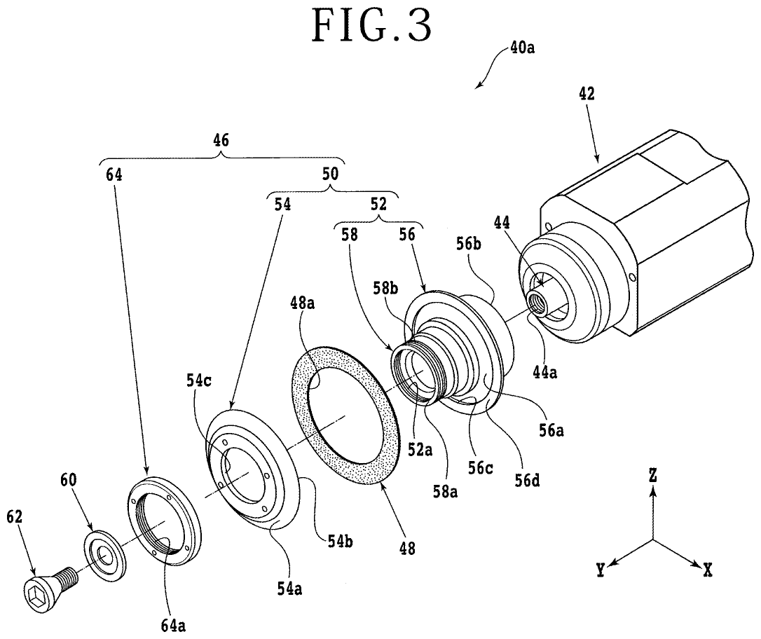

To a lower part of the Z-axis moving plate 34 constituting the cutting unit moving mechanism 22 on one side, a first cutting unit 40a is fixed. FIG. 3 is an exploded perspective view schematically depicting a structure of the first cutting unit 40a. As depicted in FIG. 3, the first cutting unit 40a includes a tubular spindle housing 42. In the spindle housing 42, a spindle 44 having an axis substantially parallel to the Y axis is accommodated.

A tip part (one end side) of the spindle 44 is exposed outside the spindle housing 42. A tip surface of the tip part of the spindle 44 is provided with a tapped hole 44a. In addition, to a base end part (the other end side) of the spindle 44, a rotational drive source (not illustrated) such as a motor is connected.

To the tip part of the spindle 44, an annular cutting blade 48 is mounted through a blade mounter 46. The blade mounter 46 includes a mount flange 50 attached to the tip part of the spindle 44. The mount flange 50 includes a fixed mount 52 fixed to the tip part of the spindle 44, and a press flange 54 for pressing the cutting blade 48 attached to the fixed mount 52.

The fixed mount 52 includes a disk-shaped flange section 56 that supports the cutting blade 48, and a cylindrical boss section 58 projecting from a central part of a circular front surface 56a (surface on one side) of the flange section 56. The fixed mount 52 is formed with a through-hole 52a that penetrates the central part of the flange section 56 from the front surface 56a side to a back surface 56b (surface on the other side) side and penetrates a central part of the boss section 58 from a tip 58a side to a base end side (flange section 56 side).

The tip part of the spindle 44 is inserted into the through-hole 52a from the back surface 56b side of the flange section 56, so that the fixed mount 52 of the mount flange 50 is mounted to the spindle 44 from the back surface 56b side of the flange section 56. The through-hole 52a is provided with an annular receiving section that receives a washer 60. The washer 60 is disposed in the through-hole 52a, and when a screw 62 is fastened into the tapped hole 44a of the spindle 44 through the washer 60, the fixed mount 52 is fixed to the tip part of the spindle 44.

At a circumferential part on the front surface 56a side of the flange section 56, an annular projection 56c slightly projecting in a direction intersecting the front surface 56a (a direction perpendicular to the front surface 56a) is provided. A tip surface 56d of the projection 56c is formed to be substantially flat. A screw thread is provided in a region on the tip 58a side of a circumferential surface 58b of the boss section 58.

The cutting blade 48 is what is generally called a washer-type cutting blade configured by an annular cutting edge having a structure in which abrasive grains of diamond or the like are dispersedly fixed by a bonding material such as metal, resin, or ceramic. In other words, in a central part of the cutting blade 48, a circular opening 48a penetrating the cutting blade 48 in its thickness direction is provided. At the time of attaching the cutting blade 48 to the fixed mount 52, the boss section 58 is inserted into the opening 48a in such a manner that a surface on one side of the cutting blade 48 is brought into contact with the tip surface 56d of the flange section 56.

In a state in which the cutting blade 48 is attached to the fixed mount 52, the press flange 54 is attached to the fixed mount 52. The press flange 54 is, for example, formed in a frustoconical shape from a material such as stainless steel and has a curved surface 54a that corresponds to a side surface of the frustoconical shape and a flat surface 54b that corresponds to a bottom surface of the frustoconical shape and is located on a side substantially opposite to the curved surface 54a.

In a central part of the press flange 54, an opening 54c penetrating the press flange 54 in its thickness direction is provided. At the time of attaching the press flange 54 to the fixed mount 52, the boss section 58 is inserted into the opening 54c. When the press flange 54 is attached to the fixed mount 52 in a state in which the cutting blade 48 is attached to the fixed mount 52, the flat surface 54b of the press flange 54 comes into contact with the other side surface of the cutting blade 48.

The blade mounter 46 further includes a blade fixing instrument 64 which is used at the time of fixing the annular cutting blade 48 to the mount flange 50. The blade fixing instrument 64 is typically an annular nut (round nut) and is provided in a central part thereof with an opening 64a into which the boss section 58 of the fixed mount 52 is inserted. An inner circumferential surface of the opening 64a is formed with a screw thread corresponding to the screw thread of the boss section 58.

At the time of fixing the cutting blade 48 to the mount flange 50, in a state in which the boss section 58 is inserted in the opening 48a of the cutting blade 48 and the opening 54c of the press flange 54, the boss section 58 is further inserted into the opening 64a of the blade fixing instrument 64. Thereafter, the boss section 58 and the blade fixing instrument 64 are rotated relative to each other, so that the boss section 58 is fastened to the blade fixing instrument 64, and the cutting blade 48 is clamped between the fixed mount 52 and the press flange 54.

As depicted in FIG. 1, at an end part on the opening 4b side of the spindle housing 42 constituting the first cutting unit 40a, a cover 66 capable of partly covering the cutting blade 48 mounted to the spindle 44 is provided. Under the cover 66, a pair of nozzles 68 capable of supplying liquid for processing (processing liquid) represented by water to the cutting blade 48 are disposed in such a manner that the cutting blade 48 is interposed therebetween.

At a position adjacent to the first cutting unit along the X axis, a camera 70 capable of imaging the workpiece 11 held by the chuck table 12 and the like is disposed. Like the first cutting unit 40a, the camera 70 is fixed to the lower part of the Z-axis moving plate 34 constituting the cutting unit moving mechanism 22 on one side.

Thus, when the Y-axis moving plate 26 on one side is moved along the Y axis by the cutting unit moving mechanism 22 on one side, the first cutting unit 40a and the camera 70 are moved (indexing-fed) along the Y axis. In addition, when the Z-axis moving plate 34 on one side is moved along the Z axis by the cutting unit moving mechanism 22 on one side, the first cutting unit 40a and the camera 70 are moved (cutting-in-fed) along the Z axis.

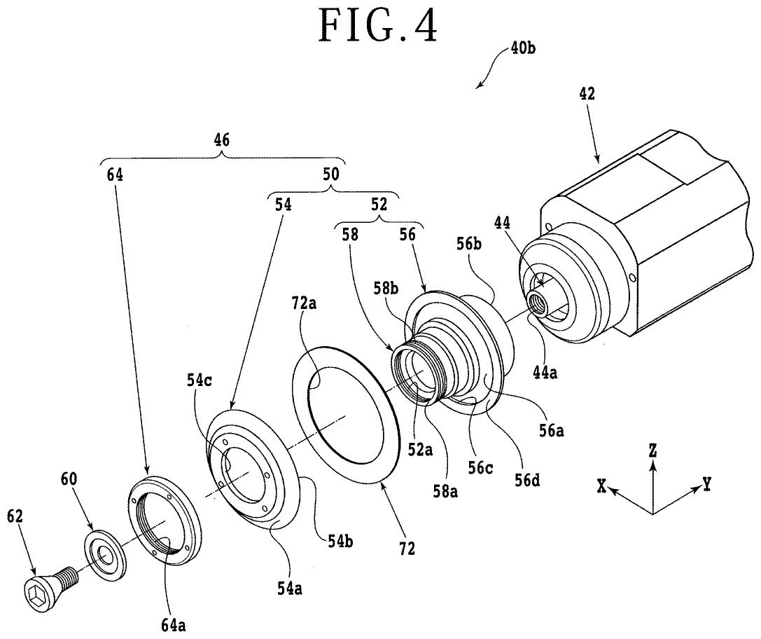

A second cutting unit 40b is fixed to a lower part of the Z-axis moving plate 34 constituting the cutting unit moving mechanism 22 on the other side. FIG. 4 is an exploded perspective view schematically depicting a structure of the second cutting unit 40b. As depicted in FIG. 4, the structure of the second cutting unit 40b is substantially the same as that of the first cutting unit 40a except that the second cutting unit 40b is configured to be symmetrical (in a relation of mirror images) with the first cutting unit 40a with respect to a plane parallel to the X axis and the Z axis. The same constituent elements as those of the first cutting unit 40a described above are denoted by the same reference symbols as used above, and overlapping descriptions are omitted.

Like the first cutting unit 40a, the second cutting unit 40b is configured such that the cutting blade 48 can be mounted to the spindle 44. It is to be noted, however, that, in the present embodiment, in place of the cutting blade 48, an annular cleaning tool 72 on the same order in size as the cutting blade 48 is mounted to the spindle 44 of the second cutting unit 40b. In other words, like the cutting blade 48, the cleaning tool 72 is also provided in a central part thereof with a circular opening 72a that penetrates the cleaning tool 72 in its thickness direction.

The cleaning tool 72 is formed of an elastic material which is soft to such an extent as not to substantially generate swarf even upon contact with the workpiece 11, and does not contain abrasive grains. Hence, even if the cleaning tool 72 makes contact with the workpiece 11, new generation of a large amount of swarf as in the case where the cutting blade 48 makes contact with the workpiece 11 would not occur, and the swarf is more suitably removed from the workpiece 11.

The cleaning tool 72 is formed, for example, of an elastic material softer than the workpiece 11 or is formed of an elastic material having a Vickers hardness of less than 10.6 GPa. Note that the cleaning tool 72 formed of an elastic material having a Vickers hardness of less than 10.6 GPa is particularly effective in the case where the workpiece 11 is formed of silicon or a material harder than silicon.

The specific material constituting the cleaning tool 72 is not particularly limited to any specific kind. For example, the cleaning tool 72 can be formed of a material such as metal, resin, or ceramic which is used for the bonding material of the cutting blade 48. It is to be noted, however, that it is desirable that the cleaning tool 72 have a solid structure with a high mechanical strength instead of a hollow (porous) structure like sponge. As a result, even if the spindle 44 is rotated at high speed, the cleaning tool 72 is not liable to be broken.

In addition, it is desirable that the cleaning tool 72 have a width (thickness) smaller than the width of a processing mark (kerf) which is formed in a groove shape (step shape) in a processed region by the cutting blade 48, such that the cleaning tool 72 can suitably be inserted into the processing mark. In other words, the cleaning tool 72 is desirably configured to be thinner than the cutting blade 48. Further, a peripheral surface of the cleaning tool 72 may be provided with a slit or the like for enhancing a swarf-discharging ability, or the peripheral surface of the cleaning tool 72 may be configured in the shape of a brush in which a fibrous material is embedded.

As depicted in FIG. 1, at a position on an opposite side of the opening 4b from the opening 4a, an opening 4c is formed. A cleaning unit 74 for cleaning the workpiece 11 obtained after processing and the like is disposed inside the opening 4c. Further, a controller (control unit) 76 is connected to the various constituent elements of the cutting apparatus 2 described above. Operations of the respective constituent elements are controlled by the controller 76.

The controller 76 is configured by a computer that includes, for example, a processing section 76a including a processing device such as a central processing unit (CPU) and a storage section 76b including a main storage device such as a dynamic random access memory (DRAM) or an auxiliary storage device such as a hard disk drive or a flash memory. The processing section 76a operates according to a program (software) stored in the storage section 76b, so that the function of the controller 76 is realized. It is to be noted, however, that the controller 76 may be realized only by hardware.

In a workpiece processing method according to the present embodiment, the workpiece 11 is processed by use of the above-described cutting apparatus 2. Specifically, first, the controller 76 of the cutting apparatus 2 takes out the workpiece 11 (the frame 23) as an object from the cassette 8 and holds the workpiece 11 (the frame 23) by the chuck table 12 (holding step).

In other words, the controller 76 of the cutting apparatus 2 operates the conveying mechanism or mechanisms to take out the workpiece 11 from the cassette 8 and place the workpiece 11 on the upper surface 16a of the chuck table 12 in such a manner that the front surface 11a side is exposed to the upper side. Thereafter, the controller 76 opens the valve in a state in which the suction source connected to the chuck table 12 is operating. As a result, the workpiece 11 is held by the chuck table 12 under a negative pressure acting on the upper surface 16a. Note that the frame 23 is fixed by the four clamps 18.

After the workpiece 11 is held by the chuck table 12, the controller 76 adjusts orientation of the chuck table 12 around its rotational axis in such a manner that one scheduled processing line 13 as an object becomes parallel to the X axis of the cutting apparatus 2 (alignment step). For example, the controller 76 specifies the position and orientation of the scheduled processing line 13 by a method such as pattern matching of detecting a characteristic pattern of the devices 15 on the basis of an image picked up by the camera 70 and rotates the chuck table 12 in such a manner that the scheduled processing line 13 as an object becomes parallel to the X axis.

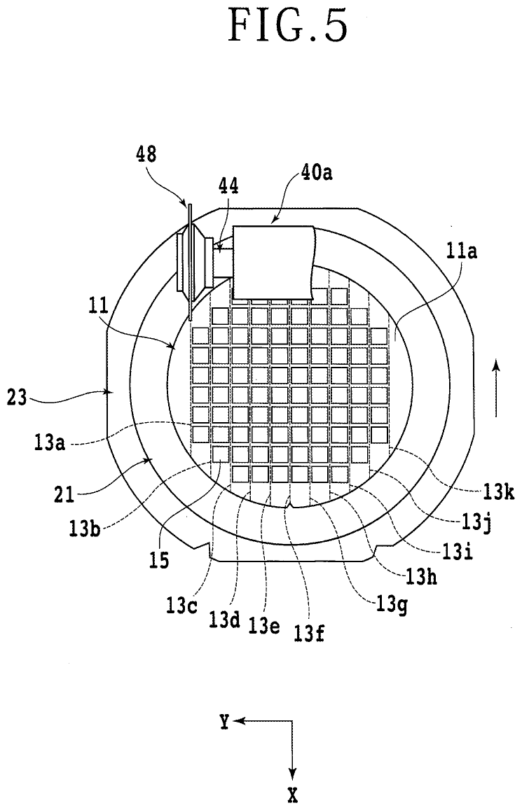

After the orientation of the chuck table 12 is adjusted according to the scheduled processing line 13 as an object, the controller 76 causes the cutting blade 48 being rotated to cut into the scheduled processing line 13 of the workpiece 11, to process the workpiece 11 (processing step). FIG. 5 is a plan view depicting the manner in which the workpiece 11 is processed along a scheduled processing line 13a located at an end of the workpiece 11. Note that, in FIG. 5, only some of the constituent elements of the cutting apparatus 2 are depicted.

First, the controller 76 adjusts a positional relation between the chuck table 12 and the first cutting unit 40a in such a manner as to match the position of the cutting blade 48 to a position above an extension of the scheduled processing line 13a as an object. Specifically, the controller 76, on the basis of the information concerning the position of the scheduled processing line 13a detected by pattern matching or the like, operates the chuck table moving mechanism 10 and the cutting unit moving mechanism 22 to match the position of the cutting blade 48 to a position above an extension of the scheduled processing line 13a.

Next, the controller 76 adjusts the positional relation between the chuck table 12 and the first cutting unit 40a in such a manner that the position (height) of a lower end of the cutting blade 48 becomes lower than the position (height) of the back surface of the workpiece 11. Specifically, the controller 76 operates the cutting unit moving mechanism 22 to match the lower end of the cutting blade 48 to a position below the back surface of the workpiece 11.

Then, the controller 76 rotates the spindle 44 (the cutting blade 48) of the first cutting unit 40a at high speed and, while supplying liquid from the nozzles 68 to the cutting blade 48, moves the chuck table 12 and the cutting blade 48 relative to each other along the scheduled processing line 13a. Specifically, the controller 76 causes the chuck table moving mechanism 10 to move the chuck table 12 in a direction along the X axis in such a manner that the cutting blade 48 being rotated cuts into the scheduled processing line 13a.

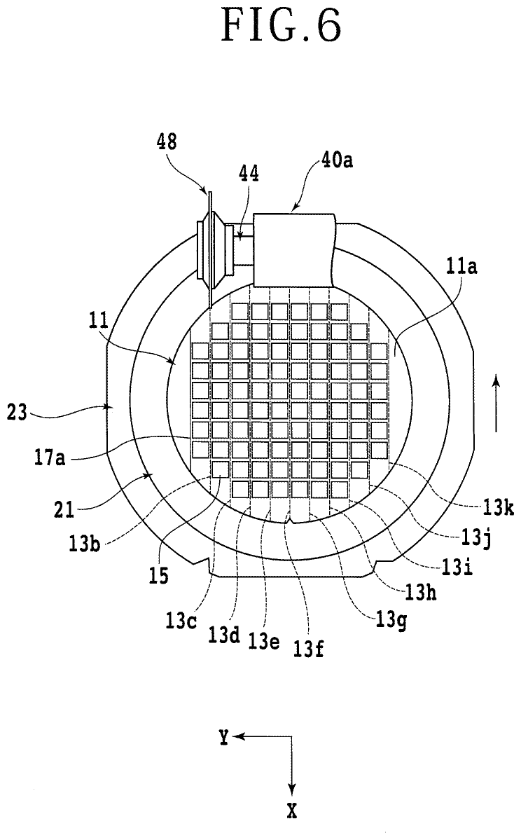

In this way, the controller 76 causes the cutting blade 48 to cut into the rectilinear scheduled processing line 13a of the workpiece 11 held by the chuck table 12, so that the workpiece 11 is processed along the scheduled processing line 13a. As a result, the workpiece 11 is cut along the scheduled processing line 13a. Note that a groove-shaped (step-shaped) processing mark (kerf) is formed in a processed region 17a (see FIG. 6 and the like) where the cutting blade 48 has cut into.

Here, the rotational speed of the cutting blade 48 is set to 10,000 rpm to 40,000 rpm, typically 30,000 rpm, the relative moving speed (processing-feed speed) of the chuck table 12 and the cutting blade 48 is set to 10 mm/s to 100 mm/s, typically 80 mm/s, and the flow rate of the liquid supplied from the nozzles 68 is set to 0.5 l/min to 3.0 l/min, typically 1.5 l/min. It is to be noted, however, that the conditions concerning the processing are not limited to these values.

After the workpiece 11 is cut at the processed region 17a (the scheduled processing line 13a), the controller 76 operates the cutting unit moving mechanism 22 to move the first cutting unit 40a in such a manner that the position of the lower end of the cutting blade 48 becomes higher than the front surface 11a of the workpiece 11. Then, the controller 76 adjusts the positional relation between the chuck table 12 and the first cutting unit 40a in such a manner as to match the position of the cutting blade 48 to a position above an extension of a scheduled processing line 13b adjacent to the processed region 17a (scheduled processing line 13a).

Specifically, the controller 76 operates the chuck table moving mechanism 10 to move the chuck table 12 in a direction along the X axis. Besides, the controller 76 operates the cutting unit moving mechanism 22 to move the first cutting unit 40a in a direction along the Y axis in such a manner as to match the position of the cutting blade 48 to a position above the extension of the scheduled processing line 13b.

Next, the controller 76 adjusts the positional relation between the chuck table 12 and the first cutting unit 40a in such a manner that the position (height) of the lower end of the cutting blade 48 becomes lower than the position (height) of the back surface of the workpiece 11. Specifically, the controller 76 operates the cutting unit moving mechanism 22 to match the lower end of the cutting blade 48 to a position lower than the back surface of the workpiece 11.

Then, the controller 76 rotates the spindle 44 (the cutting blade 48) at high speed and, while supplying liquid from the nozzles 68 to the cutting blade 48, moves the chuck table 12 and the cutting blade 48 relative to each other along the scheduled processing line 13b. Specifically, the controller 76 causes the chuck table moving mechanism 10 to move the chuck table 12 in a direction along the X axis in such a manner that the cutting blade 48 being rotated cuts into the scheduled processing line 13b.

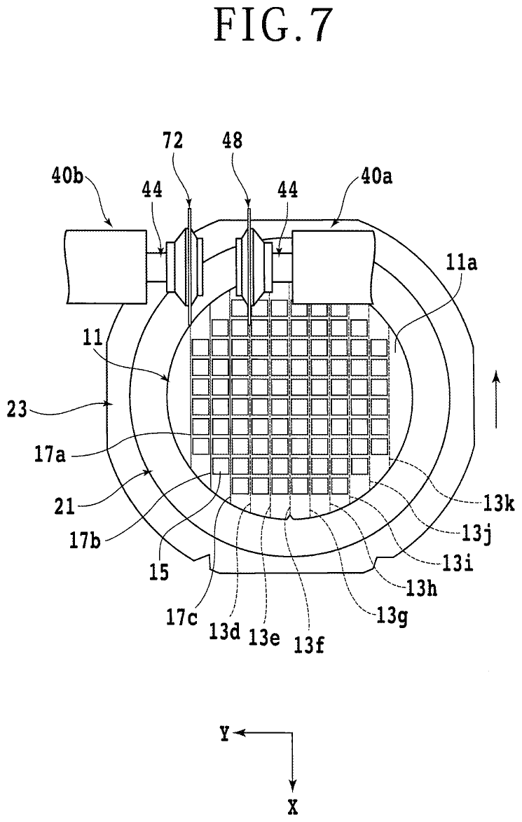

FIG. 6 is a plan view depicting the manner in which the workpiece 11 is processed along the scheduled processing line 13b. Note that, in FIG. 6, too, only some of the constituent elements of the cutting apparatus 2 are depicted. When the controller 76 causes the cutting blade 48 being rotated to cut into the scheduled processing line 13b, the workpiece 11 is cut along the scheduled processing line 13b. Note that a groove-shaped (step-shaped) processing mark (kerf) is formed at a processed region 17b (see FIG. 7 and the like) where the cutting blade 48 has cut into.

In the workpiece processing method according to the present embodiment, the above-mentioned operations are repeated, so that the workpiece 11 is cut sequentially along the scheduled processing lines 13a, 13b, 13c, 13d, 13e, 13f, 13g, 13h, 13i, 13j, and 13k. Meanwhile, swarf generated upon processing may stagnate in the processed regions 17a, 17b, and the like having been processed in a groove shape (step shape).

In view of this, in the workpiece processing method according to the present embodiment, the controller 76 brings the cleaning tool 72 being rotated close to the processed regions 17a, 17b, and the like to remove the swarf present in the processed regions 17a, 17b, and the like (swarf removing step). FIG. 7 is a plan view depicting the manner in which the swarf present in the processed region 17a is removed by the cleaning tool 72. Note that, in the present embodiment, the removal of the swarf present in the processed region 17a is carried out concurrently with the processing of the scheduled processing line 13d.

First, the controller 76 adjusts a positional relation between the chuck table 12 and the second cutting unit 40b in such a manner as to match the position of the cleaning tool 72 to a position above an extension of the processed region 17a (scheduled processing line 13a) having been processed by the cutting blade 48. Specifically, the controller 76 operates the respective cutting unit moving mechanisms 22 to match the position of the cutting blade 48 to a position above the extension of the scheduled processing line 13d and, simultaneously, match the position of the cleaning tool 72 to a position above the extension of the processed region 17a.

Next, the controller 76 adjusts the positional relation between the chuck table 12 and the second cutting unit 40b in such a manner that the position (height) of a lower end of the cleaning tool 72 becomes lower than the position (height) of the front surface 11a of the workpiece 11. Specifically, the controller 76 operates the cutting unit moving mechanism 22 to match the lower end of the cleaning tool 72 to a position lower than the front surface 11a of the workpiece 11.

Then, the controller 76 rotates the spindle 44 (cleaning tool 72) of the second cutting unit 40b at high speed and, while supplying liquid from the nozzles 68 to the cleaning tool 72, moves the chuck table 12 and the cleaning tool 72 relative to each other along the processed region 17a. Specifically, the controller 76 causes the chuck table moving mechanism 10 to move the chuck table 12 in a direction along the X axis in such a manner as to cause the cleaning tool 72 being rotated to pass through the processed region 17a formed with the processing mark.

As a result, the cleaning tool 72 is inserted into the processing mark in the processed region 17a and passes through the processing mark along the X axis. Since the cleaning tool 72 is supplied with the liquid and the cleaning tool 72 is rotated at high speed, a flow of the liquid is generated in the processing mark when the cleaning tool 72 passes through the processing mark. By the flow of the liquid, the swarf present in the processed region 17a is discharged externally.

Here, the rotating speed of the cleaning tool 72 is set, for example, to 3,500 rpm to 35,000 rpm, typically 5,000 rpm, and the flow rate of the liquid supplied from the nozzles 68 is set, for example, to 0.5 l/min to 3.0 l/min, typically 2.0 l/min. Since the removal of the swarf is carried out concurrently with the processing, the relative moving speed of the chuck table 12 and the cleaning tool 72 is basically the same as the relative moving speed of the chuck table 12 and the cutting blade 48.

It is to be noted, however, that the conditions concerning the removal of the swarf are not limited to these values. For instance, in a situation where only the removal of the swarf is conducted after the processing is completed, the relative moving speed of the chuck table 12 and the cleaning tool 72 may be set higher than the relative moving speed of the chuck table 12 and the cutting blade 48.

Specifically, the relative moving speed of the chuck table 12 and the cleaning tool 72 is set, for example, to 50 mm/s to 500 mm/s, typically 200 mm/s. In this case, the length of time required for removal of the swarf can be shortened, and a swarf removing ability (removability) can be enhanced.

In addition, to the liquid supplied from the nozzles 68 to the cleaning tool 72, a chemical agent having a predetermined cleaning power may be added. For example, when liquid containing a chemical agent having as a component a surface active agent, represented by StayClean series products made by DISCO Corporation, is supplied to the cleaning tool 72, an effect that the swarf can efficiently be removed is obtained.

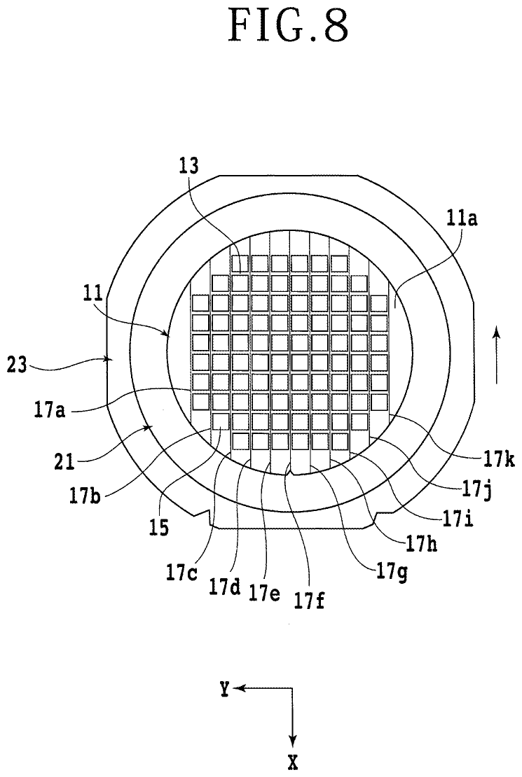

The above-described operations are repeated also for the other processed regions 17b, 17c, 17d, 17e, 17f, 17g, 17h, 17i, 17j, and 17k (see FIG. 8). For example, after the workpiece 11 is cut along the scheduled processing lines 13a, 13b, 13c, 13d, 13e, 13f, 13g, 13h, 13i, 13j, and 13k as objects and the swarf present in the processed regions 17a, 17b, 17c, 17d, 17e, 17f, 17g, 17h, 17i, 17j, and 17k as objects is removed, the workpiece processing method is finished. FIG. 8 is a plan view depicting the workpiece 11 obtained after the processing.

Since the cleaning tool 72 according to the present embodiment is formed of a soft elastic material and does not contain abrasive grains as described above, even if a positional relation between the cleaning tool 72 and the processed region 17a or the like is deviated from a proper relation and the cleaning tool 72 makes contact with the processed region 17a or the like, new generation of a large amount of swarf as in the case where the cutting blade 48 makes contact with the processed region 17a or the like would not occur. Hence, with the cleaning tool 72 and the workpiece processing method according to the present embodiment, the swarf present in the processed region 17a or the like after the processing is removed more suitably.

Note that the present invention is not limited to the description of the above embodiment and may be carried out with various modifications. For example, while the workpiece 11 is cut along the scheduled processing lines 13a, 13b, 13c, 13d, 13e, 13f, 13g, 13h, 13i, 13j, and 13k that are parallel to one another in the above embodiment, the workpiece 11 may be cut along other scheduled processing lines 13 that intersect the scheduled processing lines 13a and the like, in a similar manner. In addition, instead of being cut along the scheduled processing lines 13, the workpiece 11 may be formed with grooves along the scheduled processing lines 13.

Further, while the cutting apparatus 2 including two cutting units (the first cutting unit 40a and the second cutting unit 40b) is used in the above-described embodiment, the workpiece processing method according to the present invention may use two (or more) cutting apparatuses each including one cutting unit. Similarly, the workpiece processing method according to the present invention may use one cutting apparatus including one cutting unit. In this case, a cutting blade and a cleaning tool are selectively mounted to the spindle of one cutting unit.

Note that, in the case where a cutting apparatus including one cutting unit is used, it is desirable that the relative moving speed of the chuck table and the cleaning tool be set higher than the relative moving speed of the chuck table and the cutting blade. Specifically, the relative moving speed of the chuck table and the cleaning tool is set, for example, to 50 to 500 mm/s, typically 200 mm/s. As a result, the length of time required for removal of swarf can be shortened, and the swarf removing ability (removability) can be enhanced.

Other than those described above, the structures, methods, and the like concerning the above-described embodiment and modifications may be modified in carrying out the present invention insofar as the new modifications do not depart from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cleaning tool which is used in a state of being mounted to a spindle configured such that an annular cutting blade containing abrasive grains is mountable thereto, and which is used to remove swarf that has been generated during processing of a workpiece by use of the cutting blade and that is present in a processed region processed by the cutting blade of the workpiece, from the processed region, wherein
the cleaning tool has in its central part an opening to be used at a time of mounting to the spindle, and
the cleaning tool is formed in an annular shape from an elastic material softer than the workpiece and does not contain abrasive grains, or the cleaning tool is formed in an annular shape from an elastic material having a Vickers hardness of less than 10.6 GPa and does not contain abrasive grains.

2. A workpiece processing method to be used when processing a plate-shaped workpiece, the workpiece processing method comprising:
a processing step of causing a cutting blade being rotated to cut into the workpiece while supplying liquid to the cutting blade, to thereby process the workpiece; and
a swarf removing step of bringing a cleaning tool being rotated close to a processed region processed by the cutting blade of the workpiece while supplying liquid to the cleaning tool, to thereby remove swarf present in the processed region,
wherein the cleaning tool is formed in an annular shape from an elastic material softer than the workpiece and does not contain abrasive grains, or the cleaning tool is formed in an annular shape from an elastic material having a Vickers hardness of less than 10.6 GPa and does not contain abrasive grains.

3. The workpiece processing method according to claim 2, wherein,
in the processing step, the cutting blade is caused to cut into a rectilinear scheduled processing line set on the workpiece, to thereby form the workpiece with a rectilinear processing mark, and
in the swarf removing step, the cleaning tool is caused to pass through the processed region formed with the processing mark, to thereby remove the swarf present in the processed region.

4. The workpiece processing method according to claim 2, wherein, in the swarf removing step, the liquid supplied to the cleaning tool contains a chemical agent having a cleaning power.
